(19) United States
(12) Patent Application Publication
(10) Pub. No.: US 2006/0202332 A1
(43) Pub. Date: Sep. 14, 2006

(54) Semiconductor chip packaging apparatus and method of manufacturing semiconductor chip package

(75) Inventors: Se-Young Jeong, Seoul (KR); Gi-Young Sohn, Seoul (KR); Ki-Kwon Jeong, Cheongan-si (KR); Hyeon Hwang, Cheonan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/418,010

(22) Filed: May 5, 2006

Related U.S. Application Data
(63) Continuation-in-part of application No. 11/326,192, filed on Jan. 6, 2006.

(30) Foreign Application Priority Data
Jan. 8, 2005 (KR) 10-2005-0001950
Aug. 16, 2005 (KR) 10-2005-0074916

(51) Int. Cl. H01L 23/48

(52) U.S. Cl. 257/737

(57) ABSTRACT

Example embodiments of a semiconductor chip packaging apparatus and method thereof are disclosed. The packaging apparatus includes a plating unit that is disposed in a direction to form a conductive plating layer on external terminals of the semiconductor chip package; and a reflow unit that is disposed with the plating unit to melt the conductive plating layer. The packaging apparatus may further include a rinsing unit that is disposed with the plating unit to clean and cool the conductive plating layer. Thus, it is possible to effectively suppress the growth of whiskers on the plating layer of the external terminals, and to secure economical efficiency, reducing costs, and allowing mass production.

### PRIORITY STATEMENT

A claim of priority is made to Korean Patent Application No. 10-2005-0074916, filed on Aug. 16, 2005, in the Korean Intellectual Property Office, the disclosure of which is incorporated herein in its entirety by reference.

### CROSS-REFERENCE TO RELATED APPLICATIONS

This application also is a continuation-in-part of copending U.S. patent application Ser. No. 11/326,192 filed on Jan. 6, 2006, for which priority is claimed under 35 U.S.C. 120, which claims priority from Korean Patent Application No. 10-2005-0001950, filed on Jan. 8, 2005, the disclosure of each of which is incorporated herein in its entirety by reference.

### BACKGROUND OF THE INVENTION

1. Field of the Invention

Example embodiments of the present invention relate to a semiconductor chip packaging apparatus and a method of manufacturing a semiconductor chip package. More particularly, example embodiments of the present invention relate to an apparatus adapted to finish-processing semiconductor chip packages.

2. Description of the Related Art

In an example process of packaging a semiconductor chip, a semiconductor chip is attached to a package substrate and molded within a frame to protect it from external stimulations, e.g., conditions. Then, external terminals (leads) are connected to electrode pads of the semiconductor chip to connect the semiconductor chip to external electronic devices.

First on a wafer level, a semiconductor wafer is cut into individual semiconductor chips by a sawing process. The individual semiconductor chips are then attached to a printed circuit board (PCB) having external terminals, e.g., a lead frame. In a subsequent wire-bonding process, wires attach the electrode pads of a semiconductor chip to the external terminals. A molding process is then performed to protect the semiconductor chip.

As a final manufacturing process on the semiconductor chip package and to increase the reliability of the electrical connections between the external terminals and the external electronic devices, a finish-processing is performed. A finish-processing may refer to a process of forming a plating layer composed of a lead (Pb) or lead-containing tin (Sn) alloy on the external terminals.

However, the lead contained in the plating layer is known to be harmful to the human body. Further, electronic devices containing leads cause pollution and environmental hazards when they are disposed. Accordingly, environment-friendly products without lead are a requirement. The “Restriction of Hazardous Substances (ROHS) directive” has been issued by the European Union (EU) to restrict the use of component materials harmful to the human body and the environment, and will go into effect on July of 2006.

Tin (Sn) or a tin alloy without lead plating layer has been suggested as a substitute plating layer. However, whiskers are generated when plating external terminals with tin or a tin alloy without lead. The whiskers may cause the leads to fail, which may cause the semiconductor chip to short-circuit.

FIG. 1 is an electron microscope image of a cross sectional view of a lead 55 of a conventional semiconductor chip package. Referring to FIG. 1, a blow-up view of region a1 clearly shows whiskers 57. The whiskers 57 may cause the lead 55 to fail. Accordingly, the whiskers 57 generated on the surface of the lead 55 may cause the semiconductor chip to short-circuit and malfunction.

One reason for the generation of the whiskers 57 on the surfaces of the leads 55 may be the compressive stress applied to the tin or tin alloy plating layer. The generation of the whiskers 57 may be reduced or minimized by decreasing the applied compressive stress or by converting the compressive stress into tensile stress. For example, performing a heat treatment after the plating process, adjusting the physical property of the plating layer by optimizing the plating solution, or by forming an underlying layer of a third metal, such as nickel (Ni), silver (Ag), zinc Zn or the like, between a substrate, e.g., a lead frame, and a plating layer, may reduce the generation of the whiskers 57.

Performing the heat treatment after plating has been favored because of its simplicity. The heat treatment is performed using a separate heat treatment apparatus. After the finishing process, the semiconductor chip package is laid on a separate plastic tray, transferred to the heating apparatus, and the heat treatment is performed. For example, when a lead frame is used as the external terminals, heat treatment to suppress the growth of whiskers 57 is carried out at a temperature of about 150 to 175° C. for about 1 to 2 hours.

However, the addition of heat treatment process may have the following problems in mass production. First, a separate and additional heat treatment process may reduce product yield. Second, investment in production cost may increase due to the need to purchase the heat treatment equipment and the addition and need for space for an apparatus line. For example, substituting a 150° C. tray for the current 130° C. tray may increase production cost. Third, the heat treatment process may only suppress the whiskers 57 to a small extent for certain type of lead frames.

### SUMMARY OF THE INVENTION

Example embodiments of the present invention provide a semiconductor chip packaging apparatus capable of effectively suppressing the growth of whiskers in leads of semiconductor device.

According to an example embodiment of the present invention, there is provided a semiconductor chip package apparatus for finish-processing a semiconductor chip package, the apparatus comprising: a transporting device movable in a direction with the semiconductor chip package attached thereto; a plating unit that is disposed with the transporting device to form a conductive plating layer on external terminals of the semiconductor chip package; a reflow unit that is disposed with the plating unit to melt the conductive plating layer; a rinsing unit that is disposed with the plating unit to clean and cool the conductive plating layer; and a drying unit that is disposed with the plating unit to dry the conductive plating layer.

The plating unit, the reflow unit, the rinsing unit, and the drying unit may be sequentially disposed. The plating unit, the reflow unit, the rinsing unit, and the drying unit may be disposed in a line, for example, a linear line, an arc, or other line.

The apparatus may further include a cleaning unit disposed between the plating unit and the reflow unit to clean the conductive plating layer. The plating unit, the cleaning unit, the reflow unit, the rinsing unit, and the drying unit may be sequentially disposed. The plating unit, the cleaning unit, the reflow unit, the rinsing unit, and the drying unit may be disposed in a line, for example, a linear line, an arc, or other line.

The apparatus may further include another drying unit disposed between the cleaning unit and the reflow unit with the plating unit to dry the conductive plating layer. The plating unit, the cleaning unit, the another drying unit, the reflow unit, the rinsing unit, and the drying unit may be sequentially disposed. The plating unit, the cleaning unit, the another drying unit, the reflow unit, the rinsing unit, and the drying unit may be disposed in a line, for example, a linear line, an arc, or other line.

According to another example embodiment of the present invention, there is provided a method of finish-processing a semiconductor chip package, the method comprising: forming a conductive plating layer on external terminals of the semiconductor chip package; melting and reflowing the conductive plating layer; rinsing the reflowed plating layer to clean and cool the conductive plating layer; and drying the rinsed plating layer.

### BRIEF DESCRIPTION OF THE DRAWINGS

The present invention will become more apparent with the description of example embodiments thereof with reference to the attached drawings in which:

FIG. 1 is electron microscope image of a cross sectional view of leads of a conventional semiconductor chip package after a finish-process;

FIG. 2 is a schematic diagram of a semiconductor chip packaging apparatus for a finish-process according to an embodiment of the present invention;

FIG. 3 is a schematic diagram of a semiconductor chip packaging apparatus for a finish-process according to another embodiment of the present invention;

FIG. 4 is a perspective view of a reflow unit of the semiconductor chip packaging apparatus illustrated in FIG. 1;

FIG. 5 is a flow chart illustrating a semiconductor chip packaging method of a finish-process according to an embodiment of the present invention;

FIGS. 6 through 9 are schematic diagrams illustrating a semiconductor chip packaging method of a finish-process;

FIG. 10 is a graph of a whisker length of a lead frame according to a number of finish heat treatment cycles;

FIG. 11 is an electron microscope image of a lead frame manufactured by an embodiment of the present invention;

FIG. 12 is a schematic diagram of a semiconductor chip packaging apparatus for a finish-process according to another example embodiment of the present invention;

FIG. 13 is a perspective view of a rinsing unit of the semiconductor chip packaging apparatus of FIG. 12;

FIG. 14 is a schematic diagram of a semiconductor chip packaging apparatus for a finish-process according to another example embodiment of the present invention;

FIG. 15 is a flow chart illustrating a semiconductor chip packaging method of a finish-process according to another example embodiment of the present invention; and

FIG. 16 is a sectional view for explaining residual stress between external terminals and a plating layer of a semiconductor chip package manufactured according to the method of FIG. 15.

### DETAILED DESCRIPTION OF EXAMPLE EMBODIMENTS

The present invention will now be described more fully hereinafter with reference to the accompanying drawings, in which example embodiments of the present invention are described. The present invention may, however, be embodied in many different forms and should not be construed as being limited to the embodiments set forth herein. Rather, these embodiments are provided as working examples. Like numbers refer to like elements throughout the specification.

FIG. 2 is a schematic diagram of a semiconductor chip packaging apparatus 100 for a finish-processing according to an embodiment of the present invention.

Referring to FIG. 2, the packaging apparatus 100 may include a plating unit 130 and a reflow unit 160. The packaging apparatus 100 may be used to finish a semiconductor chip package 110. In general, a semiconductor chip package 110 may be used to connect to another electronic product, therefore, a finish-processing may increase contact reliability between the semiconductor chip package 110 and the electronic product. More specifically, the finish-processing may be a post-processing performed after forming a conductive plating layer (not shown) on external terminals (115 of FIG. 4).

A plating unit 130 may serve as a unit adapted to perform a process to form a conductive plating layer on the external terminals (115 of FIG. 4) of the semiconductor chip package 110. The conductive plating layer may be a tin (Sn) layer or a lead-free tin alloy layer (Sn alloy layer). The tin layer or Sn alloy layer being environmental-friendly and which satisfies the RoHS directive of the European Union (EU). For example, the tin alloy layer may be formed of SnCu, SnBi, SnAg, SnZn, or a combination thereof. In the example embodiments of the present invention, any reference to the tin alloy layer or a lead-free tin alloy means a layer substantially without lead.

A reflow unit 160 is a unit, which is adapted to perform a manufacturing, to increase the reliability of the conductive plating layer. For example, the reflow unit 160 may be used to melt the conductive plating layer to suppress the generation of whiskers. In this case, the plating unit 130 and the reflow unit 160 are arranged in a line along a direction x.

Accordingly, forming the conductive plating layer and performing a reflow-processing on the conductive plating layer may be successively performed. That is, it may be unnecessary to perform a reflow-processing in a separate apparatus after the formation of the conductive plating layer. Example embodiments of the present invention also may make it unnecessary to exchange current transport trays.

As shown in FIG. 2, the packaging apparatus 100 may further include a transporting device 120 to transport a semiconductor chip package 110 from the plating unit 130 to the reflow unit 160. For example, the transporting device 120 may be a conveyer belt system or any type of device capable of transporting electronic devices from one area to another. The transporting device 120 attaches the semiconductor chip package 110 thereto for transportation.

The reflow unit 160 will now be described in greater detail with reference to FIG. 4. Referring to FIG. 4, the reflow unit 160 may include a heating device 165 adapted to melt the conductive plating layer of the semiconductor chip package 110.

A heating device 165, which may be a device capable of emitting infrared rays, deep infrared rays, hot air, or a mixture thereof, as indicated by arrows 168. For example, the heating device 165 may be adapted to simultaneously emit infrared rays and hot air; infrared rays and deep infrared ray; deep infrared rays and hot air; or infrared rays, deep infrared rays, and hot air.

The transporting device 120 may pass through the reflow unit 160 with the semiconductor chip package 110 attached thereto. The semiconductor chip package 110 may have a number of semiconductor chips attached to a package frame, for example, a lead frame 115. The package frame may be a printed circuit board having another type of external terminals other than the lead frame 115 having leads. For example, the package frame may be a printed circuit board having solder balls as the external terminals.

A plating layer (not shown) of the external terminals 115 is heated and melted while the semiconductor chip package 110 passes through the heating device 165. A heating time may be determined based on a speed at which the transporting device 120 moves and/or a length L of the reflow unit 160. For example, when the speed of the transporting device 120 is determined, the length L of the reflow unit 160 may be varied to determine the amount of heat necessary to be applied to the conductive plating layer.

The length L of the reflow unit 160 may be at least about 0.75 cm to ensure that sufficient (minimum) amount of heat necessary to melt the surface of the tin plating layer or the tin alloy plating layer is irradiated thereon. Further, the heating time should be adjusted so that the melted conductive plating layer does not flow down. In other words, the melted conductive plating layer does not flow off the external terminals. Accordingly, the length L of the reflow unit 160 may be less than about 450 cm.

In an example embodiment, the reflow unit 160 may be a modified conventional finish-processing device. For example, changing a conventional hot air dryer (not shown) into the reflow unit 160 may reduce costs. A first type of hot air dryer having a length of about 64 cm and a second type of hot air dryer having a length of about 30 cm may be used as the reflow unit 160. Hence, the length L of the reflow unit 160 may range from about 30 to 75 cm to accommodate various hot air dryer.

Further, the reflow unit 160 may be arranged in a line having an existing plating unit. Accordingly, costs related to fabricating a separate finish device in which the plating unit and the reflow unit are arranged in a line with each other may be avoided.

As illustrated in FIG. 4, the reflow unit 160 may further include a gas flow system 170 for atmospheric control. In this example embodiment, an inflow of gas(es) serves to reduce or prevent the external terminals 115 from being oxidized during the reflow process. The gas may be an inert gas, such as nitrogen, or hydrogen to form a reduce atmosphere.

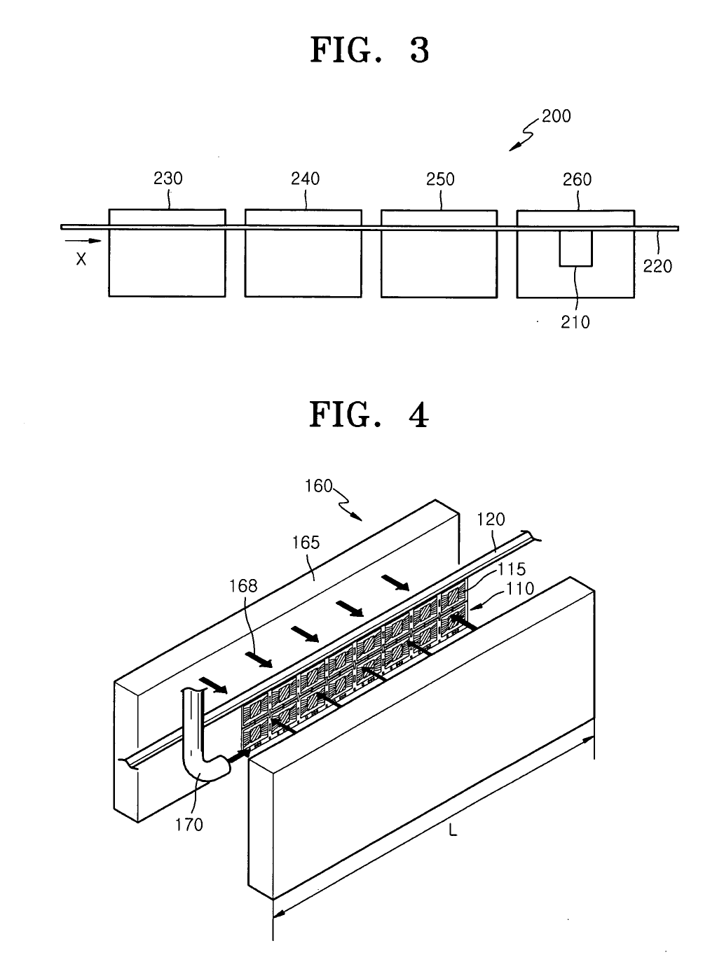

FIG. 3 is a schematic diagram of a semiconductor chip packaging apparatus 200 for a finish-processing according to another embodiment of the present invention. The semiconductor chip packaging apparatus 200 further includes a cleaning unit 240 and a drying unit 250 between a plating unit 230 and a reflow unit 260. The plating unit 230 and the reflow unit 260 are similar to the semiconductor chip packaging apparatus 100 of FIG. 2, therefore, detail descriptions thereof are omitted.

Referring to FIG. 3, the plating unit 230, the cleaning unit 240, the drying unit 250, and the reflow unit 260 are arranged in a single line along a first direction. A transporting device 220 may be a belt system or other similar transporting device. The transporting device 220 extends from the plating unit 230 to the cleaning unit 240, the drying unit 250, and the reflow unit 260. Accordingly, a semiconductor chip package 210 attached to the transporting device 220 sequentially passes through the plating unit 230 to the reflow unit 260.

The cleaning unit 240 may clean the semiconductor chip package 210 after a conductive plating process is completed on the semiconductor chip package 210. For example, the cleaning unit 240 may clean the semiconductor chip package 210 with water or any other common cleaning solution.

The drying unit 250 dries the semiconductor chip package 210 when cleaning is completed. For example, the drying unit 250 may use air or hot air as a drying device. Alternatively, the drying unit 250 may use a heating device such as an infrared device.

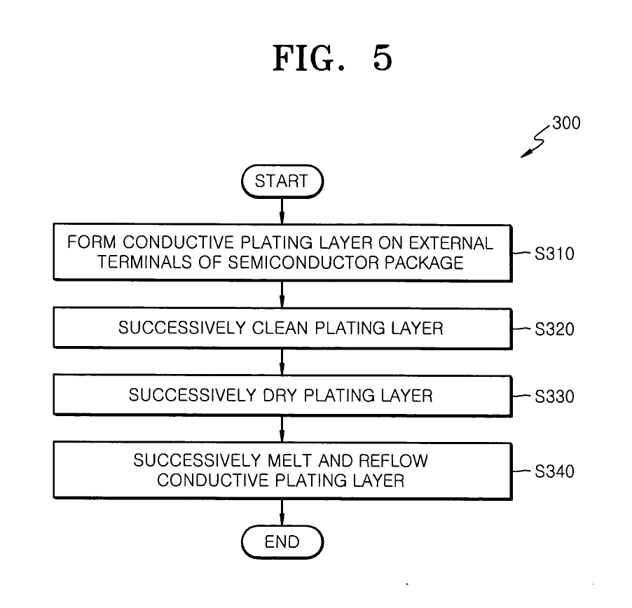

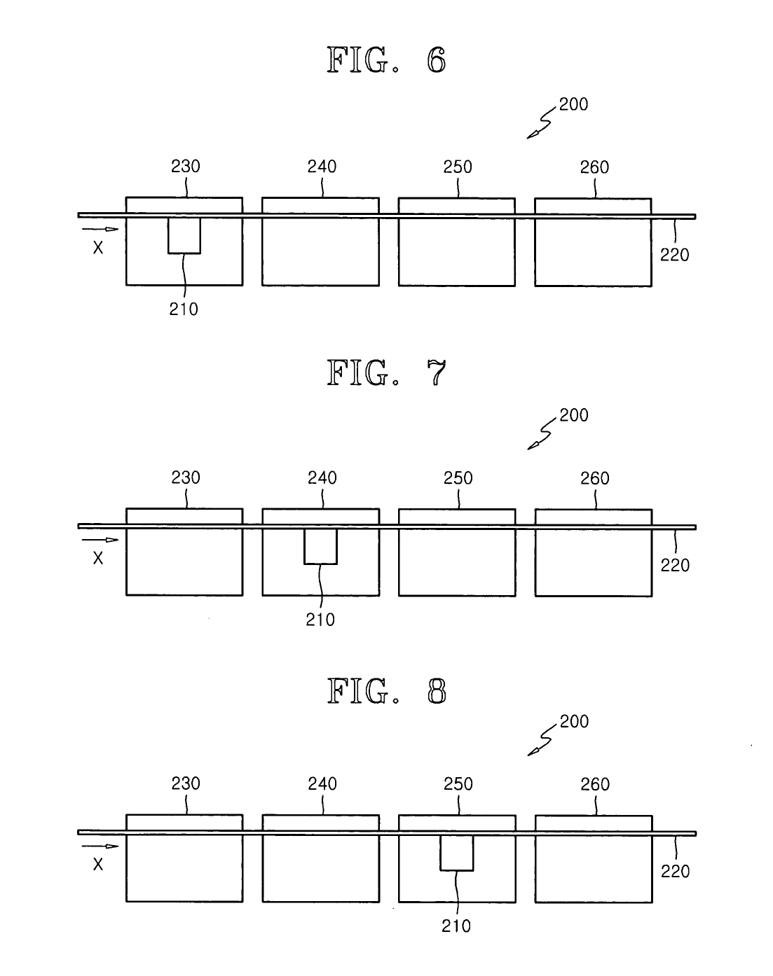

FIG. 5 is a flow chart illustrating a semiconductor chip packaging method 300 of a finish-processing according to an embodiment of the present invention. The semiconductor chip packaging method 300 will be described in greater detail also with FIGS. 6 through 9. Here, different stages of the semiconductor chip packaging method using the semiconductor chip packaging apparatus 200 are exemplarily illustrated in FIGS. 6 through 9.

Referring to FIG. 6, a conductive plating layer may be formed on the external terminals of the semiconductor chip package 210 (S310 of FIG. 5). Specifically, the transporting device 220 having the semiconductor chip package 210 thereon moves into the plating unit 230. The plating unit 230 may uses a plating solution to plate the external terminals. The plating solution may be a tin solution or a tin alloy solution. For example, the tin alloy may be SnCu, SnBi, SnAg or SnZn.

Referring to FIG. 7, after the conductive plating layer is formed on the external terminals, the semiconductor chip package 210 is cleaned (S320 of FIG. 5). For example, the transporting device 220 moves the semiconductor chip package 210 from the plating unit 230 to the cleaning unit 240. The cleaning unit 240 uses a cleaning solution such as water to clean the semiconductor chip package 210. The semiconductor chip package 210 may be moved into the cleaning unit 240 and then cleaned, or the semiconductor chip package 210 may be simultaneously cleaned while passing through the cleaning unit 240.

The cleaning process serves to remove any remaining plating solution that did not adhere to the external terminals, or may remove other impurities. The cleaning process ensures contact reliability by removing the impurities, because the impurities degrade the contact between the external terminals and the electronic product.

Referring to FIG. 8, after the cleaning the semiconductor chip package 210, the conductive plating layer is dried (S330 of FIG. 5). For example, the transporting device 220 transports the semiconductor chip package 210 from the cleaning unit 240 to the drying unit 250. In the drying unit 250, for example, compressed air may come from a wall of the drying unit 250 to dry the semiconductor chip package 210. The semiconductor chip package 210 may be moved into the drying unit 250 and then dried, or the semiconductor chip package 210 may be simultaneously dried while passing through the drying unit 250.

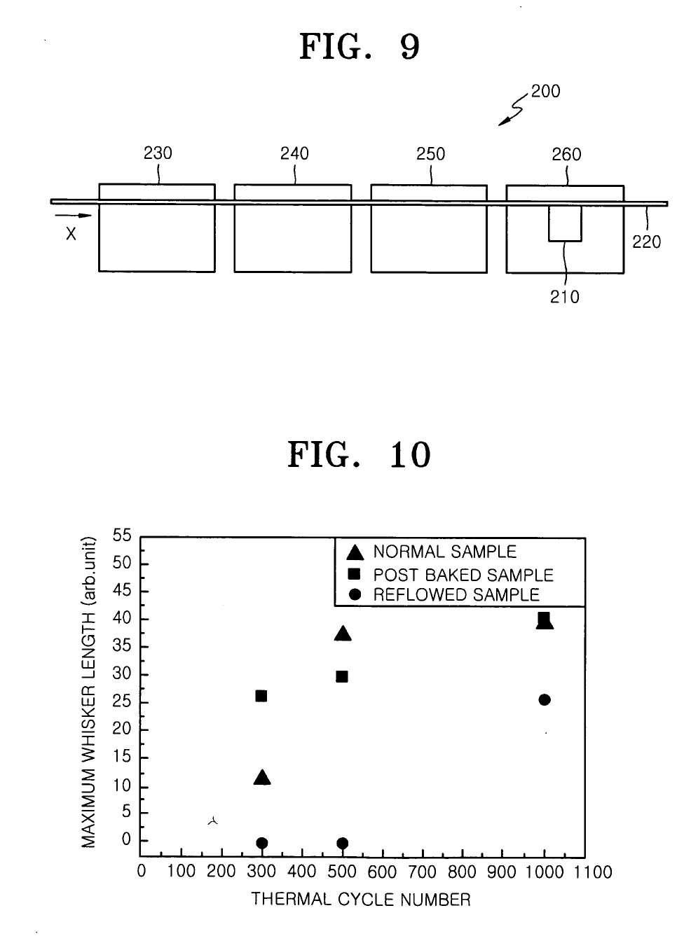

Referring to FIG. 9, a reflow processing is performed by melting the conductive plating layer of the semiconductor chip package 210 (S340 of FIG. 5). For example, the transporting device 220 may transport the semiconductor chip package 210 from the drying unit 250 to the reflow unit 260.

A heating device (see 165 of FIG. 4) may be disposed on a wall of the reflow unit 260 to melt the conductive plating layer formed on a surface of the external terminals. The heating device may heat the plating layer surface by emitting infrared rays, deep infrared rays, hot air, or a combination thereof.

A reflowing temperature may range from about 210 to 450° C. to melt the conductive plating layer. The temperature may be limited to less than about 280° C. so that the melted tin or tin alloy plating layer does not flow down. In addition, when the semiconductor chip package 210 is heated while passing through the reflow unit 260, the temperature may be restricted to about 250° C. or more to ensure that the minimum heat needed to melt the conductive plating layer is obtained. The temperature may be in a range from about 250 to 280° C.

The heating treatment in the reflow process (S340 of FIG. 5), e.g., the reflow of the external terminals may be affected by the speed of the transporting device 220, as well as by temperature. A reflow processing time may range from about 0.1 to 60 seconds depending on the speed of the transporting device 220. The package may be heated for 4 to 10 seconds to melt the conductive plating layer of the external terminals without having the conductive plating layer flow down. Thus, the speed of the transporting device 220 may be determined by the length of the reflow unit 260, the temperature, and the heating time.

Further, the reflow process (S340 of FIG. 5) may be performed under an inert atmosphere or a reducing atmosphere to reduce or prevent the plating layer from being oxidized. For example, the reflow operation may be performed under inert nitrogen or a reducing hydrogen atmosphere.

As described in FIGS. 6 through 9, a finish-processing may be performed on the semiconductor chip package 210 by successively performing a forming process (S310 of FIG. 5), a cleaning process (S320 of FIG. 5), a drying process (S330 of FIG. 5), and a reflowing process (S340 of FIG. 5) of the conductive plating layer on the semiconductor chip packaging apparatus 200.

Example embodiments of the semiconductor chip packaging apparatus 200 of the present invention are capable of performing a reflow processing along a single process line without the need of new separate equipment. Further, there is no need to exchange transport trays to perform the separate heat treatment process, which may result in cost reduction.

FIG. 10 is a graph illustrating length of whiskers of a lead frame according to a number of finish heat treatment cycles.

Referring to FIG. 10, (Δ) represents a normal sample that was not separately heat-treated; (□) represents a sample that was post baked in a separate apparatus; and (o) represents a reflowed sample subjected to a finish-processing. Maximum lengths of whiskers grown on the plating layer of the lead frame samples above were compared. The reflowed sample (o) was reflowed in a separate reflow apparatus to confirm the effects of the example embodiments of the present invention.

As can be seen from FIG. 10, in the normal sample (Δ) and the baked sample (□), whiskers having a significant length were generated after as few as 500 thermal cycles. On the other hand, the reflow-processed sample (o) had almost no whiskers after 500 thermal cycles.

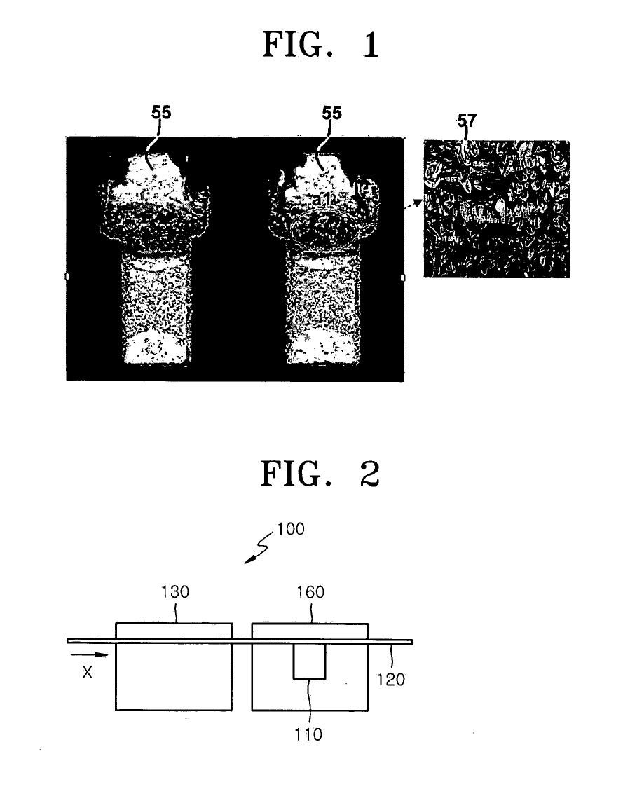

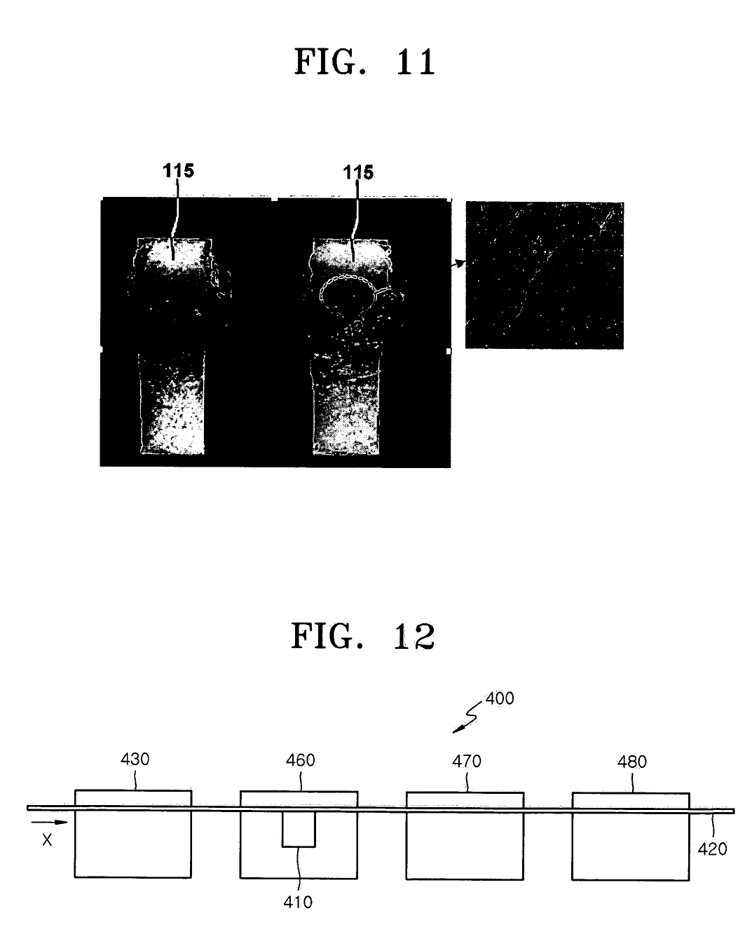

FIG. 11 is an electron microscope image of a lead frame 115 of the reflowed sample (o) after 500 thermal cycles. As can be seen from the enlarged portion a2 of the lead frame 115, no detectable whiskers were generated as compared with the whiskers 57 generated in the lead frame illustrated in FIG. 1.

In a reflow processing performed by the example embodiments of the semiconductor chip packaging apparatus of the present invention, whiskers may be effectively reduced or prevented from being generated on a plating layer of a lead frame formed of tin or a lead-free tin alloy. Therefore, by performing a finishing-processing, for example, from a plating process (S310 of FIG. 5) to a reflow process (S340 of FIG. 5) without transporting a semiconductor chip package to a separate apparatus, it may be possible to effectively suppress the generation of whiskers on the plating layer formed of tin or the lead-free tin alloy layer.

In another embodiment of the present invention, a reflow process is performed successively and directly after a plating process. In this case, the plating process and the reflow process are similar to those in the finish-processing according to the above-described embodiment.

FIG. 12 is a schematic diagram of a semiconductor chip packaging apparatus 400 for a finish-process according to another example embodiment of the present invention. The embodiment of FIG. 12 is a modification of the embodiment of FIG. 2. The embodiment of FIG. 12 differs from the embodiment of FIG. 2 in that a rinsing unit and a drying unit are further included. Like reference numerals in FIGS. 2 and 12 designate elements that are common to both figures.

Referring to FIG. 12, the semiconductor chip package apparatus 400 includes a plating unit 430, a reflow unit 460, a rinsing unit 470, a drying unit 480, and a transporting device 420. The transporting device 420 can move in a direction, for example, an X-direction, with a semiconductor chip package 410 attached thereto. The plating unit 430, the reflow unit 460, the rinsing unit 470, and the drying unit 480 may be arranged in a line in the X-direction. The plating unit 430, the reflow unit 460, the rinsing unit 470, and the drying unit 480 may be sequentially arranged in a line. The transporting device 420 may be a conveyer belt system extending between the plating unit 430 and the drying unit 480

The semiconductor chip package 110 in FIG. 4 and the descriptions thereof above may be referred to with regard to the semiconductor chip package 410. The semiconductor chip package 410 may include external terminals (reference numeral 115 in FIG. 4), for examples, a lead frame or solder balls. The plating unit 430 may be used to form a conductive plating layer on the external terminals of the semiconductor chip package 410. FIGS. 2 and 3 and the descriptions with reference to FIGS. 2 and 3 may be referred to for details of the plating unit 430. The reflow unit 460 may be used to melt the plating layer. FIG. 4 and the descriptions with reference to FIG. 4 may be referred to for details of the reflow unit 460.

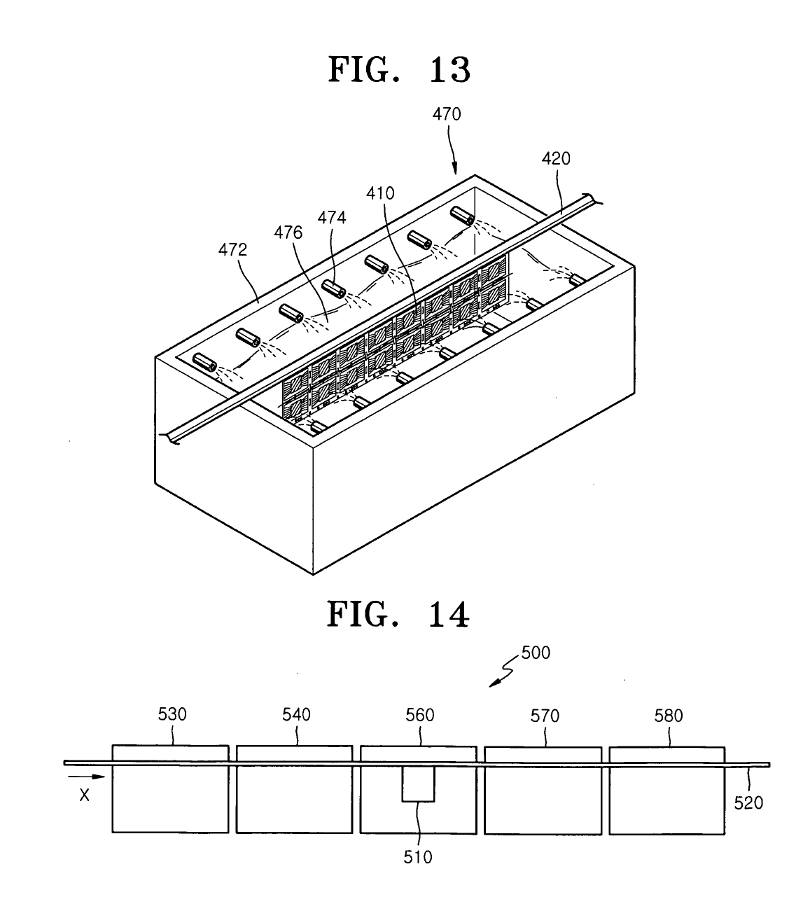

The rinsing unit 470 will be described in detail with reference to FIG. 13. The rinsing unit 470 may be used to clean and/or cool the plating layer of the semiconductor chip package 410. The processes of cleaning and/or cooling the plating layer may be performed to remove contaminants from the surface of the plating layer and/or to preserve tensile stress of the plating layer through rapid cooling of the plating layer. Preserving tensile stress of the plating layer will be described in detail later.

The rinsing unit 470 may include a bath 472 and supply devices 474 for supplying a fluid 476, for example, distilled water, into the bath 472. The bath 472 may be filled with the fluid 476 and may drain the fluid 476. Accordingly, the semiconductor chip package 410 moved into the rinsing unit 470 may be cleaned and/or cooled with the fluid 476. The plating layer of the semiconductor chip package 410 heated by the reflow unit 460 (FIG. 12) may be cleaned and rapidly cooled. In addition, the supply devices 474 may continuously supply new fluid 476 into the bath 472, thereby further increasing the cleaning and/or cooling efficiency of the rinsing unit 470.

In addition, the rinsing unit 470 may further include another supply unit (not shown) capable of rapidly supplying the fluid 476 and a drain unit (not shown) capable of rapidly dump draining the fluid 476 in a bottom surface of the bath 472. Using the additional supply unit and the drain unit, the plating layer of the semiconductor chip package 410 may be rapidly cleaned and/or rapidly cooled. The fluid 476 may be supplied at room temperature or may be supplied after being cooled to a specific temperature. In example embodiments, the cooling rate of the plating layer of the semiconductor chip package 410 may be controlled by varying the temperature of the provided fluid 476.

Referring FIG. 12, the drying unit 480 may be used to dry the plating layer of the semiconductor chip package 410. The drying unit 480 may be similar to the drying unit 250 of FIG. 3. For example, the drying unit 480 may be used to remove residual fluid from the surface of the plating layer after the plating layer is rinsed. The drying unit 480 may use, for example, air, for example, hot air, to dry the plating layer. Alternatively, the drying unit 480 may use a heating device, for example, an infrared device, to dry the plating layer. Alternatively, the drying unit 480 may use isopropyl alcohol (IPA) to dry the plating layer.

The semiconductor chip package apparatus 400 may have all the advantages of the semiconductor chip package apparatus 100 in FIG. 2. Furthermore, the semiconductor chip package apparatus 400 may preserve a tensile stress of the plating layer of the semiconductor chip package 410.

FIG. 14 is a schematic diagram of a semiconductor chip packaging apparatus 500 for a finish-process according to another example embodiment of the present invention. The embodiment of FIG. 14 is a modification of the embodiment of FIG. 12. The embodiment of FIG. 14 differs from the embodiment of FIG. 12 in that a cleaning unit is further included. FIGS. 12 and 13 and the descriptions with reference thereto and further descriptions with reference to FIGS. 2 through 11 may be referred to for details of the semiconductor chip package apparatus 500. Like reference numerals designate elements that are common to the figures.

Referring to FIG. 14, the semiconductor chip package apparatus 500 may include a plating unit 530, a cleaning unit 540, a reflow unit 560, a rinsing unit 570, a drying unit 580, and a transporting device 520. The plating unit 530, the cleaning unit 540, the reflow unit 560, the rinsing unit 570, and the drying unit 580 may be sequentially arranged in a line in a direction, for example, an X-direction. In an example embodiment, the transporting device 520 may be a conveyer belt system extending between the plating unit 530 and the drying unit 580 to carry the semiconductor chip package 520 in the X-direction.

The related description with reference to FIGS. 12 and 13 may be referred to for details of the plating unit 530, the reflow unit 560, the rinsing unit 570, the drying unit 580, and/or the transporting device 520.

The cleaning unit 540 may be used to clean the plating layer of the semiconductor chip package 520. For example, the cleaning unit 540 may be used to remove plating residues or particles adhering to the surface of the plating layer. For example, the cleaning unit 540 may be similar to the cleaning unit 240 of FIG. 3. Alternatively, although named differently, the cleaning unit 540 may be similar to the rinsing unit 470 of FIG. 12. Therefore, the related description with reference to FIGS. 3 and 12 may be referred to for details of the cleaning unit 540.

The fluid (for example, water or distilled water) remaining on the semiconductor chip package 510 which has passed through the cleaning unit 540 may be dried by heat in the reflow unit 560. In addition, the semiconductor chip package 500 may further include another drying unit (not shown) between the cleaning unit 540 and the reflow unit 560 to dry fluid (for example, water or distilled water). This additional drying unit may be similar to the drying unit 250 of FIG. 3.

The semiconductor chip package apparatus 500 may have all the advantages of the semiconductor chip package apparatus 400 in FIG. 12.

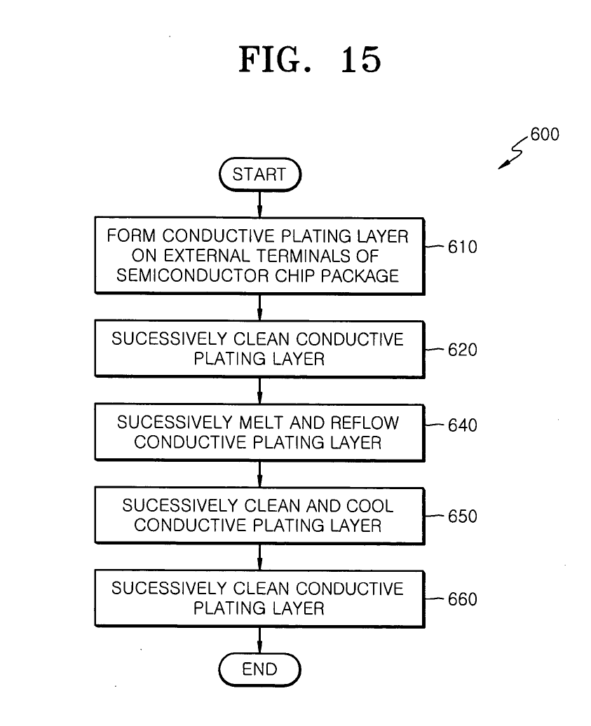

FIG. 15 is a flow chart illustrating a semiconductor chip packaging method 600 of a finish-process according to another example embodiment of the present invention. The semiconductor chip packaging method in FIG. 15 may be used in the semiconductor chip packaging apparatus 400 of FIG. 12 or the semiconductor chip packaging apparatus 500 of FIG. 14. Hereinafter, an example of the semiconductor chip packaging method of FIG. 15 will be described in connection with the semiconductor chip packaging apparatus 500 of FIG. 14. The description of the semiconductor chip packaging method of FIG. 5 may be referred to here. Like reference numerals are used to designate operations that are common to FIGS. 5 and 15.

Referring to FIGS. 14 and 15, a conductive plating layer may be formed on external terminals of the semiconductor chip package 510 in the plating unit 530 (S610). S310 of FIG. 5 may be referred to with regard to S610 of FIG. 15.

The plating layer may be successively cleaned in the cleaning unit 540 (S620). S320 of FIG. 5 may be referred to with regard to S620 of FIG. 15. Optionally, the semiconductor chip packaging method according to an example embodiment of FIG. 15 may further include a drying process (not shown). S330 of FIG. 5 may be referred to with regard to this optional drying process.

The plating layer may be successively melted and reflowed in the reflow unit 560 (S640). S340 of FIG. 5 may be referred to with regard to S640 of FIG. 15.

The plating layer may be successively cleaned and/or cooled in the rinsing unit 570 (S650). S650 of FIG. 15 will be described in detail with reference to FIG. 13. Referring to FIG. 13, the semiconductor chip package 410 may be moved into the bath 472 using the transporting device 420. In an example embodiment, the bath 472 may be move upward or the transporting device 420 may be moved downward such that the semiconductor chip package 410 may be dipped in the fluid 476 in the bath 472. The supply devices 474 may continuously supply fluid (for example, water at room temperature or distilled water cooled to a specific temperature) to the semiconductor chip package 410.

As a result, the plating residue or particle remaining on the semiconductor chip package 410, and in particular on the plating layer of the semiconductor chip package 410, may be removed. In the rinsing unit 570, supplying and draining fluid (for example, distilled water) may be repeatedly performed through an additional supply device and a drain unit, thereby further increasing the cleaning and/or cooling rates.

Referring FIGS. 14 and 15, the rinsed plating layer may be dried in the drying unit 580. For example, hot air can be supplied to the rinsed plating layer using a hot air device to remove the fluid (for example, distilled water) remaining on the plating layer. Alternatively, infrared rays may be radiated onto the rinsed plating layer to dry the plating layer.

The semiconductor chip packaging method 600 of the example embodiment in FIG. 15 may provide all the effects of the semiconductor chip packaging method in FIG. 5. Furthermore, the semiconductor chip packaging method of FIG. 15 may further preserve a tensile stress of the plating layer of the semiconductor chip package 520.

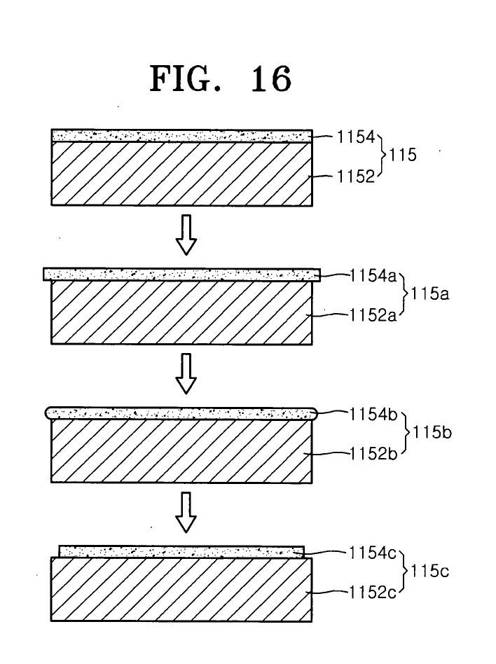

FIG. 16 is a sectional view illustrating residual stress of a plating layer on external terminals of a semiconductor chip package manufactured according to the method of FIG. 15.

Referring to FIGS. 15 and 16, an external terminal 115 may include a lead 1152 and a plating layer 1154 on the lead 1152. For example, the lead 1152 may be formed of an iron-nickel alloy, for example, Alloy 42, and the plating layer 1154 may be formed of a tin layer. When the initial residual stress of the tin layer 1154 of the external terminal 115 after S610 of FIG. 15 is denoted by a σ₀, the residual stress σ₀ of the tin layer 1154 may have a negative value or a slightly positive value depending on the plating conditions.

During S640 of heating the plating layer to reflow the same, the residual stress of the tin layer 1154a of the external terminal may decrease from σ₀ to σ₁ (σ₁<σ₀). This is because the lead 1152a and the tin layer 1154a have different thermal coefficients. For example, the lead 1152a may have a thermal expansion coefficient of, for example, about 4.4 ppm/° C., and the tin layer 1154a can have a thermal expansion coefficient of, for example, 24 ppm/° C. Accordingly, the tin layer 1154a expands more than the lead 1152a, and thus a compressive stress remains on the tin layer 1154a. That is, the residual stress σ₁ changes from a positive value to a negative value or from a negative value to a smaller negative value.

When the tin layer 1154b of the external terminal 115b is melted and reflowed in S640 of FIG. 15, the residual stress of the tin layer 1154b changes to σ₂ that is almost equal to zero. This is because the stress due to a lattice mismatch between the lead 1152b and the tin layer 1154b may be almost completely relieved.

When the external terminal 115c is cooled in S650 of FIG. 15, the tin layer 1154c shrinks more than the lead 1152c. However, due to the lattice match between the lead 1152c and the tin layer 1154c, the tin layer 1154c cannot shrink to reach equilibrium, and thus a residual tensile stress σ₃ remains on the tin layer 1154c. The greater the cooling rate of the tin layer 1154c, the larger the residual tensile stress σ₃. In other words, S650 allows the residual tensile stress σ₃ to remain on the tin layer 1154c.

It is known to one of ordinary skill in the art that whiskers are generated when a compressive residual stress is exerted on the tin layer 1154c. However, when using a semiconductor chip package apparatus and a semiconductor chip packaging method according to example embodiments of the present invention, tensile stress may remain on a plating layer, for example, a tin layer, and the generation of whiskers may be suppressed. As an effect of the residual tensile stress, the generation of whiskers caused by the reflow of the plating layer can be further suppressed. Therefore, when the plating layer is cooled successively after reflowing, such a whisker of about 20 μm in length occurring in the reflowed sample after about 1000 thermal cycles, as shown in FIG. 10, may be almost completely suppressed.

While the example embodiments of the present invention have been particularly shown and described with reference to drawings, it will be understood by those of ordinary skill in the art that various changes in form and details may be made therein without departing from the scope of the present invention.

What is claimed is:

1. A semiconductor chip package apparatus for finish-processing a semiconductor chip package, the apparatus comprising:
a transporting device movable with the semiconductor chip package attached thereto;
a plating unit that is disposed with the transporting device to form a conductive plating layer on external terminals of the semiconductor chip package;
a reflow unit that is disposed with the plating unit to melt the conductive plating layer;
a rinsing unit that is disposed with the plating unit to clean and cool the conductive plating layer; and
a drying unit that is disposed with the plating unit to dry the conductive plating layer.

2. The apparatus of claim 1, wherein the plating unit, the reflow unit, the rinsing unit, and the drying unit are sequentially disposed in a line.

3. The apparatus of claim 2, further comprising a cleaning unit disposed between the plating unit and the reflow unit with the plating unit to clean the conductive plating layer.

4. The apparatus of claim 3, further comprising another drying unit disposed between the cleaning unit and the reflow unit with the plating unit to dry the conductive plating layer.

5. The apparatus of claim 2, wherein the reflow unit comprises a heating device for melting the conductive plating layer.

6. The apparatus of claim 5, wherein the heating device emits infrared rays, deep infrared rays, hot air, or a combination thereof.

7. The apparatus of claim 2, wherein a length of the reflow unit is in a range of about 30 to 75 cm in the direction of the line.

8. The apparatus of claim 2, wherein the conductive plating layer comprises a tin layer or a lead-free tin alloy layer.

9. The apparatus of claim 8, wherein the tin alloy layer comprises SnCu, SnBi, SnAg, or SnZn.

10. The apparatus of claim 2, wherein the reflow unit comprises a gas flow device to control an ambient within the reflow unit.

11. The apparatus of claim 10, wherein the gas flow device injects an inert gas for preventing oxidation of the conductive plating layer or a reductive gas for preventing oxidation of the conductive plating layer.

12. The apparatus of claim 2, wherein the transporting device is a conveyer belt system.

13. The apparatus of claim 2, wherein the rinsing unit comprises a bath and a supply device supplying distilled water into the bath.

14. A method of finish-processing a semiconductor chip package, the method comprising:
forming a conductive plating layer on external terminals of the semiconductor chip package;
melting and reflowing the conductive plating layer;
rinsing the reflowed plating layer to clean and cool the conductive plating layer; and
drying the rinsed plating layer.

15. The method of claim 14, wherein forming the plating layer including plating a tin layer or a lead-free tin alloy layer on the external terminals.

16. The method of claim 15, wherein the tin alloy layer is SnCu, SnBi, SnAg, or SnZn.

17. The method of claim 14, wherein the reflowing is performed by heating the semiconductor chip package.

18. The method of claim 17, wherein the heating comprises emitting infrared rays, deep infrared rays, hot air, or a combination thereof.

19. The method of claim 14, wherein the reflowing is performed at a temperature about 210 to 450° C.

20. The method of claim 19, wherein the reflowing is performed at a temperature of 250 to 280° C.

21. The method of claim 19, wherein the reflowing is performed for 0.1 to 60 seconds.

22. The method of claim 21, wherein the reflowing is performed for 4 to 10 seconds.

23. The method of claim 14, wherein the reflowing is performed in a gas ambient to prevent oxidation of the plating layer.

24. The method of claim 23, wherein the gas ambient is a nitrogen ambient or a hydrogen ambient.

25. The method of claim 14, further comprising cleaning the conductive plating layer between the plating and the reflowing.

26. The method of claim 25, further comprising drying the cleaned plating layer between the cleaning and the reflowing.
